(19) United States
(12) Patent Application Publication
(10) Pub. No.: US 2020/0225516 A1
(43) Pub. Date: Jul. 16, 2020

(54) Display Substrate, Display Panel and Display Device

(71) Applicants: ORDOS YUANSHENG OPTOELECTRONICS CO., LTD., Ordos, Inner Mongolia (CN); BOE TECHNOLOGY GROUP CO., LTD., Beijing (CN)

(72) Inventors: Yadong QIU, Beijing (CN); Peirong HUO, Beijing (CN); Zhiqiang WANG, Beijing (CN); Peng LUO, Beijing (CN)

(21) Appl. No.: 16/640,866

(22) PCT Filed: May 17, 2019
(86) PCT No.: PCT/CN2019/087449

§ 371 Date: Feb. 21, 2020

(30) Foreign Application Priority Data
May 24, 2018 (CN) 201810508751.2

(51) Int. Cl. G02F 1/13; H01L 27/12; G09G 3/00

(52) U.S. Cl. CPC G02F 1/1309; G09G 3/006; H01L 27/124

(57) ABSTRACT

The present disclosure provides a display substrate, a display panel and a display device. The display substrate includes a display area and a peripheral area around the display area located on a base substrate, the peripheral area includes a first peripheral region at a side of the display substrate, the display substrate includes a test circuit located in the first peripheral region and including a signal output terminal. The test circuit further includes a first signal line, a second signal line and a switch structure located in the first peripheral region, and the switch structure is coupled to the first signal line, the second signal line and the signal output terminal; the switch structure is turned on under the control of a turn-on signal output by the second signal line, so that the first signal line is electrically coupled with the signal output terminal.

### CROSS REFERENCE TO RELATED APPLICATIONS

The present disclosure claims priority to Chinese patent application No. 201810508751.2 filed on May 24, 2018, the entire disclosure of which is incorporated herein by reference.

### TECHNICAL FIELD

The present disclosure relates to the field of display technology, and in particular, to a display substrate, a display panel, and a display device.

### BACKGROUND

With the mobile phone screen with high screen ratio becoming the mainstream of the market, narrowing the bezel and releasing the edge space become one of the main efforts for the panel design at present.

In the display panel of the related art, a Cell Test Data (CTD) unit is disposed above a multiplexer (MUX) unit and at a same side of the display panel as the MUX unit, and a common MUX unit is used for CT_SWITCH. In such design, the common electrode signal line (VCOM) and the common electrode switch control line (VCOM_SWITCH) surround the screen of the display panel.

### SUMMARY

An embodiment of the present disclosure provides a display substrate, which includes a display area and a peripheral area around the display area on a base substrate. The peripheral area includes a first peripheral region at a side of the display substrate. The display substrate includes a test circuit, which is located in the first peripheral region and includes a signal output terminal. The test circuit further includes a first signal line, a second signal line, and a switch structure, which are located in the first peripheral region. The switch structure is coupled with the first signal line, the second signal line and the signal output terminal, and the switch structure is turned on under the control of a turn-on signal output by the second signal line, so that the first signal line is electrically coupled with the signal output terminal.

In some implementations, the test circuit further includes a signal input terminal configured to input a driving signal for the test circuit, the first signal line, the second signal line, and the switch structure are located between the signal input terminal and the signal output terminal.

In some implementations, the switch structure is further configured to be turned off under the control of a turn-off signal output by the second signal line to decouple the first signal line from the signal output terminal.

In some implementations, the signal output terminal includes a plurality of output pins, the switch structure includes switch transistors corresponding to the output pins. Control electrodes of the switch transistors are coupled to the second signal line; first electrodes of the switch transistors are coupled to the first signal line; and second electrodes of the switch transistors are coupled to the output pins in one-to-one correspondence.

In some implementations, the switch transistors include thin film transistors.

In some implementations, the first electrodes of the switch transistors are source electrodes of the thin film transistors, the second electrodes of the switch transistors are drain electrodes of the thin film transistors, and the control electrodes of the switch transistors are gate electrodes of the thin film transistors.

In some implementations, the first signal line is a common electrode signal line, and the second signal line is a common electrode switch control line.

In some implementations, the display substrate is an array substrate. Another embodiment of the present disclosure provides a display panel including an opposite substrate and the display substrate described above, which are oppositely disposed.

Yet another embodiment of the present disclosure provides a display device including the above display panel.

In some implementations, the display panel is a liquid crystal display panel.

### DESCRIPTION OF DRAWINGS

FIG. 1 is a schematic structural diagram of a display substrate in the related art;

FIG. 2 is a schematic structural diagram of a display substrate according to an embodiment of the disclosure;

FIG. 3 is a partial schematic diagram of a first peripheral region in FIG. 2.

### DETAILED DESCRIPTION

In order to make those skilled in the art better understand the technical solutions of the present disclosure, a display substrate, a display panel and a display device provided in the present disclosure are described in detail below with reference to the accompanying drawings.

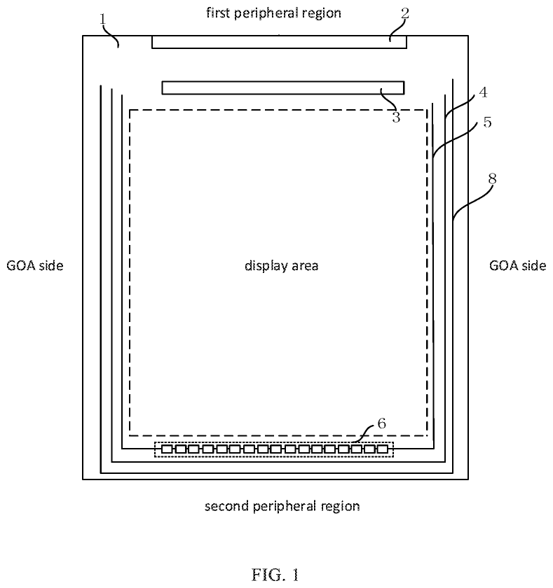

FIG. 1 is a schematic structural diagram of a display substrate in the related art. As shown in FIG. 1, a display area and a peripheral area around the display area are disposed on a display substrate, the peripheral area includes a first peripheral region (a region where a test circuit is located), a second peripheral region opposite to the first peripheral region, and GOA (Gate On Array) side regions. The display substrate includes a base substrate 1, and an input terminal 2 and an output terminal 3 located on the base substrate 1, where the input terminal 2 and the output terminal 3 are located in the first peripheral region. The display substrate further includes a test circuit including a first signal line (i.e., a common electrode signal line) 4, a second signal line (i.e., a common electrode switch control line) 5 and a switch structure 6 which are positioned on the base substrate 1, where the first signal line 4 and the second signal line 5 surround the screen of the display panel. The first signal line and the second signal line in the related art occupy a relative large space, and influence the peripheral capacitances to a certain extent, so that the capacitances of the GOA side regions and the second peripheral region are relative high, where the capacitances are capacitances of a touch control circuit, thus the uniformity of the capacitances of the display panel is reduced.

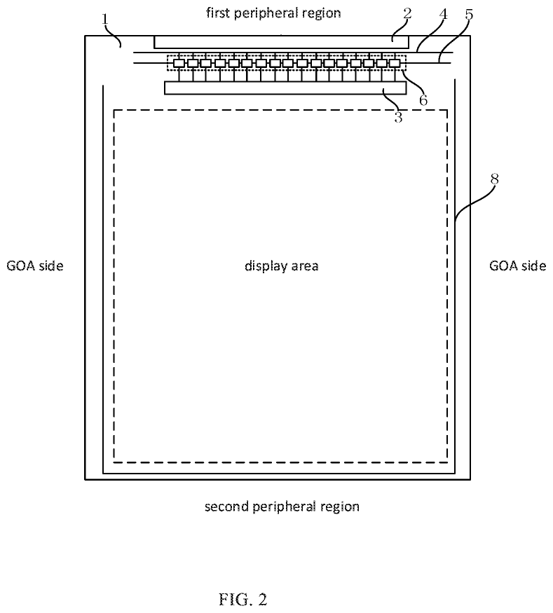

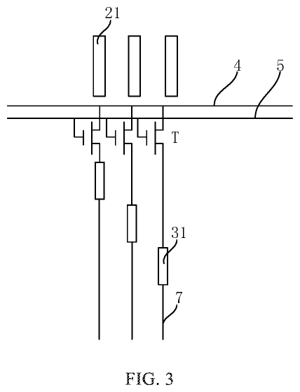

FIG. 2 is a schematic structural diagram of a display substrate according to an embodiment of the disclosure, and FIG. 3 is a partial schematic diagram of the first peripheral region in FIG. 2, as shown in FIG. 2 and FIG. 3, the display substrate includes a display area (indicated by a dotted line) and a peripheral area around the display area, the peripheral area includes a first peripheral region located at a side of the display panel, a second peripheral region opposite to the first peripheral region, and GOA side regions. The display substrate includes a base substrate 1, an input terminal 2 and an output terminal 3 located on the base substrate 1, where the input terminal 2 and the output terminal 3 are located in the first peripheral region. The display substrate further includes a test circuit including a first signal line 4, a second signal line 5 and a switch structure 6 which are located on the base substrate 1, where the switch structure 6 is coupled with the first signal line 4, the second signal line 5 and the output terminal 3. The switch structure 6 is configured to be turned on under the control of a turn-on signal output by the second signal line 5 to electrically couple the first signal line 4 to the output terminal 3.

In the present embodiment, the first signal line 4, the second signal line 5, and the switch structure 6 may be located between the signal input terminal 2 and the signal output terminal 3.

Furthermore, the switch structure 6 is also configured to be turned off under the control of a turn-off signal output by the second signal line 5, so as to decouple the first signal line 4 from the signal output terminal 3. Since the display substrate includes four side regions, the peripheral area includes four side regions, i.e., a first peripheral region, a second peripheral region and two GOA side regions, where the first peripheral region is opposite to the second peripheral region, and the two GOA side regions are opposite to each other. There is a relative large empty space between the signal input terminal 2 and the output terminal 3, therefore the first signal line 4, the second signal line 5, and the switch structure 6 may be disposed in this empty space.

As shown in FIG. 3, the signal input terminal 2 includes a plurality of input pins 21. The number of the input pins 21 may be configured according to the design requirements of the product, and only three input pins 21 are illustrated in FIG. 3 as an example.

As shown in FIG. 3, the signal output terminal 3 includes a plurality of output pins 31. The number of the output pins 31 may be configured according to the design requirements of the product, and only three output pins 31 are illustrated in FIG. 3 as an example.

As shown in FIG. 3, the switch structure 6 includes switch transistors T respectively corresponding to the output pins 31. In other words, the switch structure 6 includes a plurality of switch transistors T, and the switch transistors T are arranged in one-to-one correspondence with the output pins 31. Control electrodes of the switch transistors T are coupled to the second signal line 5, first electrodes of the switch transistors T are coupled to the first signal line 4, and second electrodes of the switch transistors T are coupled to the output pins 31 in one-to-one correspondence. The switch transistors T are turned on under the control of the turn-on signal output by the second signal line 5, so that the first signal line 4 is electrically coupled with the signal output terminal 3 through the turned-on switch transistors T. For example, the second signal line 5 outputs a turn-on signal at a high level, the switch transistors T are turned on under the control of the high level signal, and at this time, the first signal line 4 is electrically coupled with the signal output terminal 3. The switch transistors T are turned off under the control of a turn-off signal output by the second signal line 5, so that the first signal line 4 is decoupled from the signal output terminal 3 through the switch transistors T. For example, the second signal line 5 outputs a turn-off signal, which is a low level signal, the switch transistors T are turned off under the control of the low level signal, and at this time, the first signal line 4 is decoupled from the signal output terminal 3.

In the present embodiment, the switch transistors T may include thin film transistors (TFTs).

Furthermore, the signal output terminal is coupled to the display area through touch panel metal (TPM) lines. As shown in FIG. 3, the output pins 31 are coupled to the display area through the TPM lines 7.

Furthermore, as shown in FIG. 2, the display substrate further includes a ground (GILD) line 8 on the base substrate 1. The ground line 8 may be located in the second peripheral region and the GOA side regions.

After the display panel is formed by aligning and assembling the display substrate in the present embodiment with an opposite substrate, it is necessary to perform a lighting test for the display panel. In the lighting state, the second signal line 5 outputs a turn-on signal, the switch transistors T are turned on under the control of the turn-on signal, and at this time, the first signal line 4 is electrically coupled with the signal output terminal 3. The common electrode signal output by the first signal line 4 is output to the display area sequentially through the respective output pins 31 and TPM lines. After the lighting test of the display panel is completed, the second signal line 5 outputs a turn-off signal, the switch transistors T are turned off under the control of the turn-off signal, that is, the switch transistors T are suspended, the first signal line 4 is decoupled from the signal output terminal 3, at this time, a display signal may be normally output to the display area through the signal input terminal and the signal output terminal, and the switch transistor T in a turn-off state would not influence the normal output of the display signal.

In the present embodiment, the display substrate may be an array substrate, the opposite substrate may be a color filter substrate, and the display panel may be a liquid crystal display panel.

In the solution of the display substrate provided in the present embodiment, the first signal line, the second signal line and the switch structure are all located in the first peripheral region, so that the space between the input terminal and the output terminal is fully utilized, the edge space of the second peripheral region and the GOA side regions is released, and a display with narrow bezel is realized. Since the first signal line, the second signal line and the switch structure do not occupy the edge space of the second region and the GOA side regions, the capacitances of the second peripheral region and the GOA side regions are reduced, and the uniformity of the capacitances of the display panel is improved.

Another embodiment of the present disclosure provides a display panel including an opposite substrate and a display substrate disposed opposite to each other.

The display substrate provided in any above embodiment may be used as the display substrate of the present embodiment, and details thereof are not repeated herein.

In the present embodiment, the display substrate may be an array substrate, the opposite substrate may be a color filter substrate, and the display panel may be a liquid crystal display panel.

In the solution of the display substrate provided in the present embodiment, the first signal line, the second signal line and the switch structure are all located in the first peripheral region, so that the space between the input terminal and the output terminal is fully utilized, the edge space of the second peripheral region and the GOA side regions is released, and a display with narrow bezel is realized. Since the first signal line, the second signal line and the switch structure do not occupy the edge space of the second region and the GOA side regions, the capacitances of the second peripheral region and the GOA side regions are reduced, and the uniformity of the capacitances of the display panel is improved.

Still another embodiment of the present disclosure provides a display device including the display panel provided in the above embodiment.

In the solution of the display substrate provided in the present embodiment, the first signal line, the second signal line and the switch structure are all located in the first peripheral region, so that the space between the input terminal and the output terminal is fully utilized, the edge space of the second peripheral region and the GOA side regions is released, and a display with narrow bezel is realized. Since the first signal line, the second signal line and the switch structure do not occupy the edge space of the second region and the GOA side regions, the capacitances of the second peripheral region and the GOA side regions are reduced, and the uniformity of the capacitances of the display panel is improved.

It is to be understood that the above embodiments are merely exemplary embodiments employed for illustrating the principles of the technical solutions of the present disclosure, and the present disclosure is not limited thereto. It will be apparent to those skilled in the art that various changes and modifications may be made without departing from the spirit of the present disclosure, and these changes and modifications should be construed as falling within the scope of the present disclosure.

1. A display substrate, comprising a display area and a peripheral area around the display area on a base substrate, the peripheral area comprising a first peripheral region at a side of the display substrate, the display substrate comprising a test circuit, which is located in the first peripheral region and comprises a signal output terminal, wherein,
the test circuit further comprises a first signal line, a second signal line, and a switch structure, which are located in the first peripheral region,
the switch structure is coupled with the first signal line, the second signal line and the signal output terminal, and the switch structure is turned on under the control of a turn-on signal output by the second signal line, so that the first signal line is electrically coupled with the signal output terminal.

2. The display substrate of claim 1, the test circuit further comprises a signal input terminal configured to input a driving signal for the test circuit, wherein the first signal line, the second signal line, and the switch structure are located between the signal input terminal and the signal output terminal.

3. The display substrate of claim 1, wherein the switch structure is further configured to be turned off under the control of an turn-off signal output by the second signal line to decouple the first signal line from the signal output terminal.

4. The display substrate of claim 1, the signal output terminal comprises a plurality of output pins, the switch structure comprises switch transistors corresponding to the output pins;
control electrodes of the switching transistors are coupled to the second signal line;
first electrodes of the switching transistors are coupled to the first signal line; and
second electrodes of the switch transistors are coupled to the output pins in one-to-one correspondence.

5. The display substrate of claim 4, the switch transistors comprise thin film transistors.

6. The display substrate of claim 5, wherein the first electrodes of the switch transistors are source electrodes of the thin film transistors, the second electrodes of the switch transistors are drain electrodes of the thin film transistors, and the control electrodes of the switch transistors are gate electrodes of the thin film transistors.

7. The display substrate of claim 6, wherein the first signal line is a common electrode signal line, and the second signal line is a common electrode switch control line.

8. The display substrate of claim 1, the display substrate is an array substrate.

9. A display panel, comprising an opposite substrate and a display substrate opposite each other, the display substrate comprising the display substrate of claim 1.

10. A display device, comprising the display panel of claim 9.

11. The display device of claim 10, wherein the display panel is a liquid crystal display panel.

12. The display substrate of claim 2, wherein the switch structure is further configured to be turned off under the control of an turn-off signal output by the second signal line to decouple the first signal line from the signal output terminal.

13. The display substrate of claim 2, the signal output terminal comprises a plurality of output pins, the switch structure comprises switch transistors corresponding to the output pins;
control electrodes of the switching transistors are coupled to the second signal line;
first electrodes of the switching transistors are coupled to the first signal line; and
second electrodes of the switch transistors are coupled to the output pins in one-to-one correspondence.

14. The display substrate of claim 13, the switch transistors comprise thin film transistors.

15. The display substrate of claim 14, wherein the first electrodes of the switch transistors are source electrodes of the thin film transistors, the second electrodes of the switch transistors are drain electrodes of the thin film transistors, and the control electrodes of the switch transistors are gate electrodes of the thin film transistors.

16. The display substrate of claim 15, wherein the first signal line is a common electrode signal line, and the second signal line is a common electrode switch control line.

17. The display substrate of claim 3, the signal output terminal comprises a plurality of output pins, the switch structure comprises switch transistors corresponding to the output pins;
control electrodes of the switching transistors are coupled to the second signal line;
first electrodes of the switching transistors are coupled to the first signal line; and
second electrodes of the switch transistors are coupled to the output pins in one-to-one correspondence.

18. The display substrate of claim 17, the switch transistors comprise thin film transistors.

19. The display substrate of claim 18, wherein the first electrodes of the switch transistors are source electrodes of the thin film transistors, the second electrodes of the switch transistors are drain electrodes of the thin film transistors, and the control electrodes of the switch transistors are gate electrodes of the thin film transistors.

20. The display substrate of claim 19, wherein the first signal line is a common electrode signal line, and the second signal line is a common electrode switch control line.
